(19) United States
(12) Patent Application Publication
(10) Pub. No.: US 2026/0226656 A1
(43) Pub. Date: Aug. 6, 2026

(54) METHOD FOR MANUFACTURING SILICON CARBIDE SINGLE CRYSTAL AND APPARATUS FOR MANUFACTURING SILICON CARBIDE SINGLE CRYSTAL

(71) Applicant: DENSO CORPORATION, Kariya-city (JP)

(72) Inventors: Naohiro SUGIYAMA, Kariya-city (JP); Hidetaka TAKABA, Kariya-city (JP); Hiroyuki KONDO, Kariya-city (JP); Masaki MATSUI, Kariya-city (JP); Hiroki YUKAWA, Kariya-city (JP); Nobuyuki OYA, Kariya-city (JP)

(21) Appl. No.: 19/575,186

(22) Filed: Mar. 23, 2026

Related U.S. Application Data
(63) Continuation of application No. PCT/JP2024/031477, filed on Sep. 2, 2024.

(30) Foreign Application Priority Data
Sep. 22, 2023 (JP) 2023-159117

(51) Int. Cl. C30B 29/36; C30B 23/00; C30B 35/00

(52) U.S. Cl. CPC C30B 29/36; C30B 23/00; C30B 35/002

(57) ABSTRACT

A method for manufacturing a silicon carbide single crystal includes: preparing a hollow cylindrical crucible including a bottomed cylindrical container body, a lid covering an opening of the container body, and a cover member made of a metal carbide having a melting point higher than a growth temperature of silicon carbide; and growing the silicon carbide single crystal by supplying a sublimation gas of a silicon carbide raw material disposed in the container body toward a seed crystal composed of a silicon carbide substrate disposed on the lid. In the preparing, the cover member has a tubular shape along a side surface of a growth space and covers a predetermined region that is a part of the side surface from a height position of a surface of the seed crystal.

### CROSS-REFERENCE TO RELATED APPLICATIONS

The present application is a continuation application of International Patent Application No. PCT/JP2024/031477 filed on September 2, 2024, which designated the U.S. and claims the benefit of priority from Japanese Patent Application No. 2023-159117 filed on September 22, 2023. The entire disclosures of all of the above applications are incorporated herein by reference.

### TECHNICAL FIELD

The present disclosure relates to a method for manufacturing a silicon carbide (SiC) single crystal and an apparatus for manufacturing a SiC single crystal, which are used for manufacturing a SiC single crystal.

### BACKGROUND

Conventionally, as a method for manufacturing a SiC single crystal in which a SiC single crystal is grown in a crucible by a heating unit disposed around an outer periphery of a graphite crucible, for example, a sublimation recrystallization method is known. In the sublimation recrystallization method, a seed crystal is disposed in an upper part of a graphite crucible, and a SiC powder raw material disposed at a bottom part of the crucible is heated, for example, to 2300 degrees Celsius (°C) to sublimate the SiC powder raw material, thereby recrystallizing the sublimated gas on the seed crystal set to a temperature lower than the temperature of the raw material.

### SUMMARY

According to an aspect of the present disclosure, a method for manufacturing a silicon carbide single crystal includes: preparing a hollow cylindrical crucible that includes a bottomed cylindrical container body, a lid closing an opening of the container body, and a cover member disposed inside the container body and made of a metal carbide having a melting point higher than a growth temperature of silicon carbide; and growing the silicon carbide single crystal on a seed crystal, which is composed of a silicon carbide substrate and disposed on the lid, by supplying a sublimation gas of a silicon carbide raw material disposed in the container body. A space in the crucible from a height position of a surface of the seed crystal to a height position of a surface of the silicon carbide raw material and that is filled with the sublimation gas is referred to as a growth space, and a wall surface of the growth space is referred to as a side surface. In the preparing of the crucible, the cover member has a tubular shape along the side surface and may cover a predetermined region that is a part of the side surface from the height position of the surface of the seed crystal and corresponds to 5% or more and 80% or less of an area of the side surface.

### BRIEF DESCRIPTION OF THE DRAWINGS

Features and advantages of the present disclosure will become more apparent from the following detailed description made with reference to the accompanying drawings, in which:

FIG. 1 is a diagram illustrating a configuration of a SiC single crystal manufacturing apparatus in a cross-sectional view according to a first embodiment;

FIG. 2 is a diagram illustrating a relationship between a coverage ratio of a cover member on a side surface in a growth space and a carbon inclusion density in a SiC single crystal;

FIG. 3 is a diagram illustrating a configuration of a SiC single crystal manufacturing apparatus in a cross-sectional view according to a second embodiment;

FIG. 4 is a perspective view of a skirt portion;

FIG. 5 is a diagram illustrating a carburization treatment of a cover member covering the skirt portion;

FIG. 6 is a diagram illustrating a configuration of a SiC single crystal manufacturing apparatus in a cross-sectional view according to a third embodiment; and

FIG. 7 is a diagram illustrating a modification of the SiC single crystal manufacturing apparatus according to the third embodiment.

### DETAILED DESCRIPTION

In a SiC single crystal manufacturing apparatus as a related art, a truncated cone-shaped skirt portion expanding in a tapered shape is disposed around a seed crystal, and the entire area of the surface of the skirt portion is covered with a tantalum carbide (TaC) member made of tantalum carbide. The TaC member is formed into a cup shape along an inner wall surface of the skirt portion by deep drawing a plate-shaped TaC, and thus has a seamless shape. Therefore, the TaC member restricts graphite of the inner wall surface of the skirt portion from being exposed. As a result, the SiC single crystal manufacturing apparatus can suppress (i) incorporation, into a SiC single crystal grown on the seed crystal, of carbon derived from the graphite of the skirt portion, which would otherwise reduce crystal quality, and (ii) generation of defects caused by seams or breaks of the TaC member.

On the other hand, in this type of SiC single crystal manufacturing apparatus, it has been newly found that when the entire area of the inner wall surface of a crucible in which a SiC powder raw material is disposed is covered with a covering material having a melting point higher than that of SiC, such as TaC, carbon atoms become insufficient and silicon becomes excessive, and conversely the crystal quality of the SiC single crystal deteriorates. Therefore, the present inventors have studied locally exposing a partial region of the inner wall surface of the crucible at a position far from the seed crystal. As the result of the study, it has further been found that when the production of a SiC single crystal is repeated, the partial region is consumed and a hole is formed in the crucible. In such a case, drawbacks occur in that dust generated due to the hole being formed in the crucible is incorporated into the SiC single crystal, or gas obtained by sublimating the SiC powder raw material is released to the outside of the crucible through the hole.

The present disclosure provides a method for manufacturing a SiC single crystal and an apparatus for manufacturing a SiC single crystal, which are capable of suppressing deterioration of crystal quality of a SiC single crystal due to incorporation of carbon derived from graphite of a crucible and due to local consumption of the crucible.

According to an aspect of the present disclosure, a method for manufacturing a silicon carbide single crystal includes: preparing a crucible having a hollow cylindrical shape, the crucible including a bottomed cylindrical container body, a lid closing an opening of the container body, and a cover member disposed inside the container body and made of a metal carbide having a melting point higher than a growth temperature of silicon carbide; arranging a seed crystal on the lid; arranging a silicon carbide raw material in the container body; and growing the silicon carbide single crystal on the seed crystal by supplying a sublimation gas of the silicon carbide raw material. A space in the crucible from a height position of a surface of the seed crystal to a height position of a surface of the silicon carbide raw material and that is filled with the sublimation gas is referred to as a growth space, and a wall surface of the growth space is referred to as a side surface. In the preparing of the crucible, the cover member has a tubular shape along the side surface, and covers a predetermined region that is a part of the side surface from the height position of the surface of the seed crystal.

According to the method described above, the crucible including the container body, the lid, and the cover member is prepared. After the seed crystal is arranged on the lid and the SiC raw material is arranged in the container body, the SiC raw material is sublimated to grow the SiC single crystal on the seed crystal. The tubular cover member, which is made of the metal carbide having the melting point higher than the growth temperature of SiC, is prepared, and disposed to cover a part of the side surface of the growth space, which is the space in the crucible from the height position of the surface of the seed crystal to the height position of the surface of the SiC raw material and filled with the sublimation gas of the SiC raw material. The region covered with the cover member is a predetermined region that is a part of the side surface from the height position corresponding to the surface of the seed crystal toward the SiC raw material. In this method, since graphite of the side surface of the crucible in the vicinity of the surface of the seed crystal is covered with the cover member, incorporation of carbon derived from the graphite into the SiC single crystal can be suppressed. In addition, since graphite with a sufficient area is exposed in a region of the side surface far from the surface of the seed crystal surface, it is possible to suppress local consumption of the crucible and generation of holes.

According to another aspect of the present disclosure, an apparatus for manufacturing a silicon carbide single crystal includes a crucible. The crucible includes: a bottomed cylindrical container body; a lid closing an opening of the container body and to which a seed crystal composed of a silicon carbide substrate is to be attached; and a cover member disposed inside the container body and made of a metal carbide having a melting point higher than a growth temperature of silicon carbide. In the crucible, a position corresponding to a surface of a silicon carbide raw material to be disposed in the container body is referred to as a raw material height position, and a position corresponding to a surface of the seed crystal to be attached to the lid is referred to as a seed crystal height position. Further, a space from the raw material height position to the seed crystal height position and that is filled with a sublimation gas of the silicon carbide raw material is referred to as a growth space, and a wall surface of the growth space in the crucible is referred to as a side surface. The cover member has a tubular shape along the side surface and covers a predetermined region that is a part of the side surface from the seed crystal height position toward the raw material height position.

According to the apparatus described above, in the growth space from the seed crystal height position to the raw material height position in the crucible, the predetermined region of the side surface, which is a part of the side surface from the seed crystal height position and exposed to the sublimation gas, is covered with the cover member made of the metal carbide having the melting point higher than that of SiC. Since graphite of the side surface of the crucible is covered in the vicinity of the surface of the seed crystal, incorporation of carbon derived from the graphite into the SiC single crystal can be suppressed. Further, since graphite is exposed in a region of the side surface far from the seed crystal surface, it is possible to suppress local consumption of the crucible and generation of holes, while suppressing silicon in the sublimation gas of the raw material from becoming excessive.

Hereinafter, embodiments of the present disclosure will be described below with reference to the drawings. In the following description, portions that are the same or equivalent to each other are denoted by the same reference numerals throughout the embodiments.

### First Embodiment

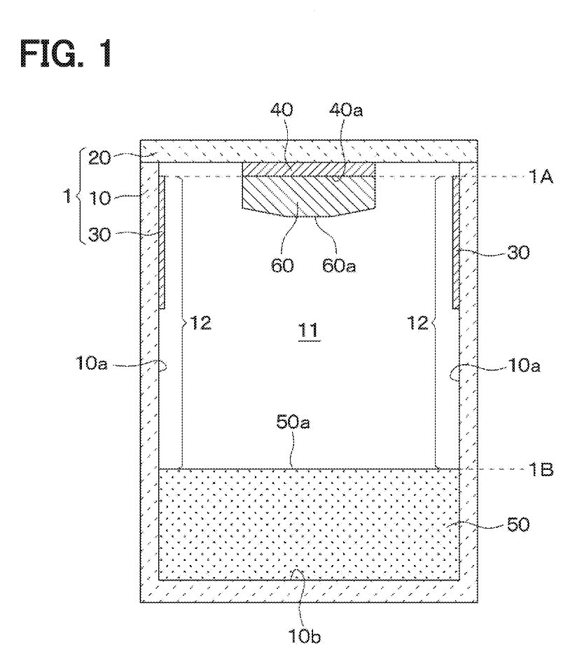

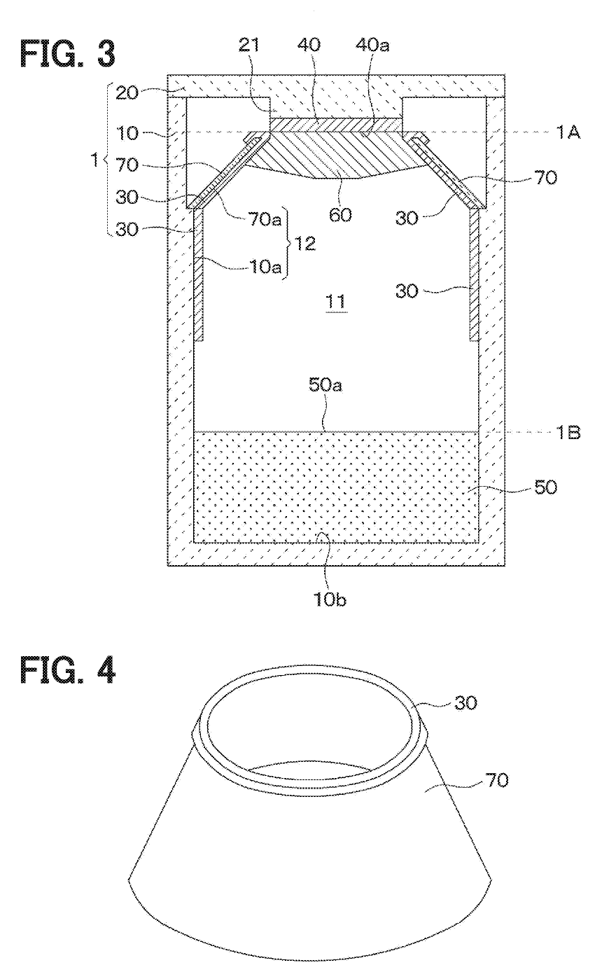

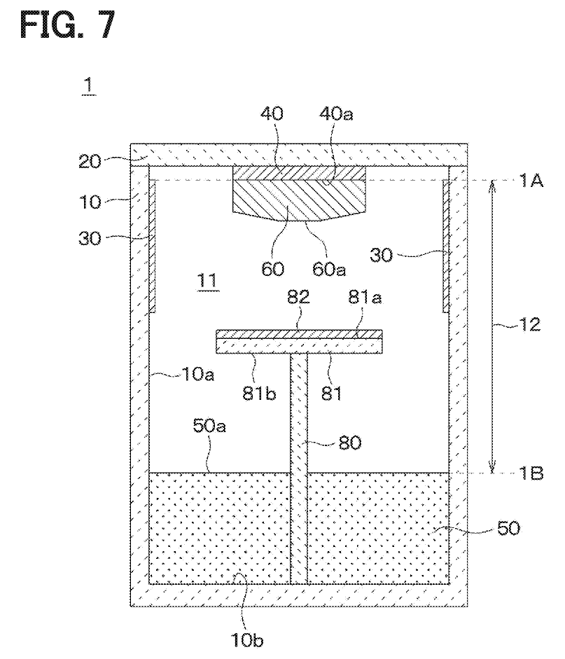

A SiC single crystal manufacturing apparatus according to a first embodiment will be described with reference to the drawings. In FIG. 1, for ease of understanding the manufacturing method, a seed crystal 40 and a raw material 50 disposed in a crucible 1 described later, and a SiC single crystal 60 grown on the seed crystal 40 are illustrated, although those are not parts of the SiC single crystal manufacturing apparatus. The same applies to FIG. 3, FIG. 6, and FIG. 7 described later.

### Basic Configuration

As illustrated in FIG. 1, for example, the SiC single crystal manufacturing apparatus includes a crucible 1 including a bottomed cylindrical container body 10, a circular lid 20, and a cover member 30. The crucible 1 has, for example, a hollow cylindrical shape, and the container body 10 and the lid 20 are made of graphite.

In the container body 10, for example, a SiC raw material 50 serving as a supply source of sublimation gas is disposed on an inner cylindrical bottom portion. The raw material 50 is, for example, powdery SiC crystal. The container body 10 has an upward opening on the lid 20 side, and a wall surface of the container body 10 on the raw material 50 side is defined as an inner wall surface 10a. In the inner wall surface 10a, a predetermined region from an upper side is covered with the cover member 30. In the present embodiment, the predetermined region of the inner wall surface 10a, which is a part of the inner wall surface 10a from a height position corresponding to a surface 40a of the seed crystal 40, is covered with the cover member 30, and a remaining region of the inner wall surface 10a is exposed. When the powdery SiC crystal raw material 50 is sublimated, a Si-excessive sublimation gas, such as Si or Si₂C, is generated. Therefore, if a side surface 12 described later is entirely covered with the cover member 30, carbon in the SiC single crystal may become insufficient, and crystal quality may deteriorate. Further, it is difficult to adjust a Si/C ratio in the powdery SiC crystal raw material 50 to suppress generation of the Si-excessive sublimation gas. For this reason, a part of the inner wall surface 10a of the container body 10 is not covered with the cover member 30, so that carbon atoms from the exposed graphite in that part are used for recrystallization of SiC, thereby playing a role of suppressing deterioration of the crystal quality due to the Si-excessive sublimation gas. For example, in the inner wall surface 10a, the entirety of a lower region that begins from a position separated from the surface 40a of the seed crystal 40 by a predetermined distance on the raw material 50 side is not covered with the cover member 30. Since the inner wall surface 10a has a large uncovered area, occurrence of local consumption during a growth process of the SiC single crystal is suppressed.

Hereinafter, for convenience of description, as illustrated in FIG. 1, a position corresponding to the surface 40a of the seed crystal 40 in the crucible 1 is referred to as a “height position 1A” or a seed crystal height position, and a position corresponding to a surface 50a of the raw material 50 is referred to as a “height position 1B” or a raw material height position. The “height position” here means, for example, a position in a height direction, and the height direction is a direction connecting a bottom surface 10b inside the crucible 1 and the opening closed by the lid 20 along a normal direction to the bottom surface 10b. Hereinafter, in the height direction described above, the lid 20 side may be referred to as “upward” or “upper side” and the bottom surface 10b side inside the container body 10 may be referred to as “downward” or “lower side”. In addition, in the crucible 1, a space from the height position 1A to the height position 1B and that is filled with the sublimation gas of the raw material 50 is referred to as a “growth space 11”, and a wall surface facing the growth space 11 is referred to as the “side surface 12”.

For example, when the surface 50a is made flat by a method such as tapping the crucible 1 after the raw material 50 is put into the container body 10, the position of the surface 50a of the raw material 50 is the position of the flat surface. For example, when the surface 50a of the raw material 50 is not made flat, the position of the surface 50a is an average position in the height direction of unevenness of the outermost surface on the seed crystal 40 side of the raw material 50, or an average position in the height direction of a portion in contact with the inner wall surface 10a among the outermost surface. Because the thickness of the seed crystal 40 is thin and negligible, a region below a height position of a surface of the lid 20 to which the seed crystal 40 is attached may be regarded as the growth space 11. Further, for example, when a region where the raw material 50 is arranged in the container body 10 is defined as a raw material arrangement region, and some mark indicating an upper end of the raw material arrangement region is attached to the inner wall surface 10a, a region above the mark may be regarded as the growth space 11.

In the present embodiment, the side surface 12 is a part of the inner wall surface 10a of the container body 10 and is provided by a portion exposed to the sublimation gas of the raw material 50. The dimension of the side surface 12 in the height direction is, for example, about 30 mm to 500 mm, although it depends on the height of the raw material 50 from the bottom surface 10b, that is, the amount of the raw material 50. The dimension of the side surface 12 in the height direction is a dimension of the growth space 11, and can be appropriately changed according to the size and thickness of the SiC single crystal 60 to be obtained.

The lid 20 is, for example, disk-shaped, and the SiC seed crystal 40 is attached to a surface of the lid 20 closing the opening of the container body 10. The seed crystal 40 is, for example, a SiC substrate, and is attached such that the surface 40a faces in a direction opposite to the lid 20.

The cover member 30 is made of a carbide having a melting point higher than a growth temperature of SiC described later, and is a member covering the predetermined region of the inner wall surface 10a of the container body 10 from the height position 1A of the seed crystal 40. The cover member 30 is provided to suppress graphite from being exposed in the region near the seed crystal 40 in the inner wall surface 10a of the container body 10, and consequently to suppress carbon particles from the graphite from being incorporated into the SiC single crystal 60 grown on the seed crystal 40, and to suppress quality deterioration of the crystal.

Hereinafter, for convenience of description, an end of the cover member 30 on the seed crystal 40 side may be referred to as an “upper end”, and an end on the raw material 50 side may be referred to as a “lower end”. The cover member 30 entirely covers the region of the side surface 12 located from the upper end to the lower end of the cover member 30. The upper end of the cover member 30 coincides, for example, with the height position 1A, that is, the position of the surface 40a of the seed crystal 40.

The cover member 30 is made of, for example, a carbide of any one of tantalum, niobium, tungsten, and titanium. The cover member 30 is attached, for example, to a partial region of the side surface 12 from the height position 1A toward the height position 1B, and has a tubular shape along the side surface 12. For example, when the part of the side surface 12 covered by the cover member 30 is defined as a covered portion, and a ratio of an area of the covered portion to an entire area of the side surface 12 is defined as a coverage ratio, the cover member 30 is disposed so that the coverage ratio is in a predetermined range described later.

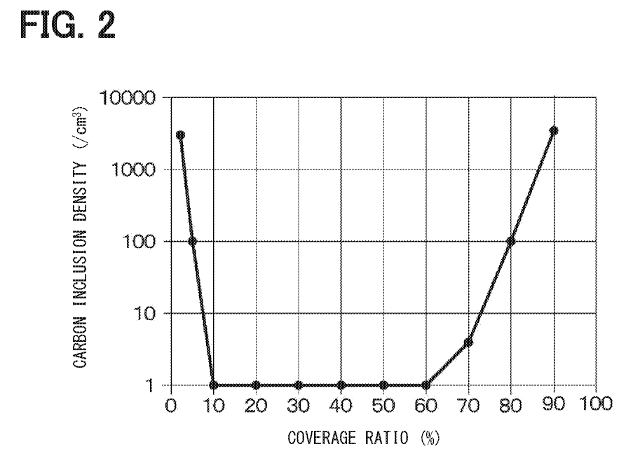

Specifically, as illustrated in FIG. 2, when the coverage ratio is in a range from 10% to 60%, a carbon inclusion density, which is a content density of carbon particles mixed in the SiC single crystal 60, is 1 cm⁻³ or less, and the crystal quality is favorable. When the coverage ratio becomes less than 10%, the carbon inclusion density begins to increase and becomes about 100 cm⁻³ at the coverage ratio of 5%. Further, when the coverage ratio becomes less than 5%, the carbon inclusion density further increases dramatically and exceeds 1000 cm⁻³. Further, when the coverage ratio exceeds 60%, the carbon inclusion density begins to increase and becomes about 100 cm⁻³ at a coverage ratio of 80%. Further, when the coverage ratio exceeds 80%, the carbon inclusion density further increases dramatically and exceeds 1000 cm⁻³. These results indicate that by setting the coverage ratio in a range from 5% to 80%, more preferably in a range from 10% to 60%, favorable crystal quality of the SiC single crystal 60 can be ensured.

The carbon inclusion density along the vertical axis in FIG. 2 is obtained by growing the SiC single crystal 60 up to a height position corresponding to a lower-limit height position on the raw material 50 side of the part of the side surface 12 covered with the cover member 30, extracting a substrate crystal having a thickness of 1 mm from the surface 60a of the SiC single crystal 60, and measuring the extracted substrate crystal. The carbon inclusion density in FIG. 2 was obtained by observing the substrate crystal having the thickness of 1 mm with an optical microscope and counting the number of carbon inclusions having a diameter of 1 µm or more confirmed in a predetermined area of the substrate crystal. Further, according to the study by the present inventors, results were obtained indicating that the carbon inclusion density of the SiC single crystal 60 does not depend on the inner diameter or dimension in the height direction of the side surface 12.

The cover member 30 is obtained, for example, by preparing a plate material having a thickness of 0.1 mm to 3 mm made of the metal material described above, processing the plate material into a shape along the inner wall surface 10a of the container body 10, and thereafter performing carburization treatment. For example, a graphite member having a shape along the inner wall surface 10a of the container body 10 is prepared, and in a state where the processed plate material disposed adjacent to the graphite member, heat treatment is performed at 1500 °C or higher and to 2500 °C or lower in an inert atmosphere, for example, an argon atmosphere, to carburize the plate material. For example, through the above process, the cover member 30 made of a metal carbide is obtained. As a result, compared to a case where a metal carbide is formed as a coating layer by a film-forming method such as chemical vapor deposition (CVD), even when the diameter of the side surface 12 is, for example, 6 inches or more, the cover member 30 without pinholes or cracks can be formed, and the SiC single crystal 60 can be manufactured stably.

When the cover member 30 is made of, for example, tantalum carbide, a C/Ta ratio, which is a ratio of carbon to tantalum, is in a range from 0.2 to 1. This is based on results of performing crystal growth using cover members made of tantalum carbide having the C/Ta ratios of 0, 0.2, 0.4, 0.6, 0.8, and 1.0 and confirming deformation and damage states of the cover member 30 accompanying the crystal growth. When the C/Ta ratio was in a range from 0.2 to 1, favorable crystal growth was possible. On the other hand, when the C/Ta ratio is less than 0.2, there is a possibility that the cover member 30 may be damaged due to a change in dimension change becoming excessively large when growing the SiC single crystal 60 and partial silicidation resulting in a low melting point. This result did not depend on the coverage ratio of the cover member 30.

For example, when the cover member 30 is made of tantalum carbide and the C/Ta ratio is in a range from 0.2 to 1, a rate of change in dimension and weight due to the carburization treatment is 1% or more and 10% or less with reference to the dimension and weight before the carburization treatment. Specifically, when the C/Ta ratio was less than 0.2, the rate of change in dimension and weight of the cover member 30 during the SiC crystal growth process was large, exceeding 10%, and deformation or breakage occurred. On the other hand, when the C/Ta ratio is in the range from 0.2 to 1, since changes in dimension and weight of the cover member 30 occur in advance in the carburization treatment, large deformation and breakage of the cover member 30 during the SiC crystal growth process can be suppressed. The dimension of the cover member 30 before the carburization treatment is preferably determined in consideration of the rate of change in dimension and weight due to the carburization treatment, so that the dimension after the carburization treatment is substantially the same as the inner diameter of the inner wall surface 10a.

The C/Ta ratio in the tantalum carbide described above can be calculated, for example, by the following method. First, a tantalum member after the carburization treatment is pulverized, and X-ray diffraction measurement is performed on the obtained powder. Regarding various peaks obtained by this X-ray diffraction measurement, peak heights derived from respective crystal phases of TaC of NaCl structure, trigonal Ta₃C₂ and Ta₄C₃, hexagonal Ta₂C, and body-centered cubic Ta are confirmed, and the proportion of each crystal phase is identified. Note that carbon ratios in the structures described above are: 1 for TaC of NaCl structure; 0.67 to 0.75 for trigonal Ta₃C₂ and Ta₄C₃; 0.5 for hexagonal Ta₂C; and 0 for body-centered cubic Ta. Then, the C/Ta ratio in each growth phase can be identified from the lattice constant of each crystal phase, and the C/Ta ratio in tantalum carbide can be calculated from the overall proportion. Therefore, it is considered sufficient that the average C/Ta ratio in the entire region of the cover member 30 is in the range from 0.2 to 1.

Further, the SiC single crystal manufacturing apparatus includes a heating unit (not illustrated) disposed so as to surround an outer periphery of the crucible 1.

The above is the configuration of the SiC single crystal manufacturing apparatus according to the present embodiment.

### Method for Manufacturing SiC Single Crystal

Next, an example of a method for manufacturing the SiC single crystal 60 using the above SiC single crystal manufacturing apparatus will be described.

First, as illustrated in FIG. 1, for example, a crucible 1 having a container body 10, a lid 20, and a cover member 30 is prepared. A seed crystal 40 is attached to an inner surface of the lid 20, and a raw material 50 is placed on a bottom surface 10b of the container body 10. As the seed crystal 40, for example, a seed crystal having a substantially circular plate shape with a diameter in a range of 150 mm to 220 mm is prepared.

Subsequently, for example, the crucible 1 is installed in a heating chamber (not illustrated), and heated by an arbitrary heating unit such as a heater fixed in position, so that the crucible 1 is heated by the radiant heat to bring the inside of the crucible 1 to a predetermined temperature. At this time, for example, the growth space 11 in the crucible 1 is set to an Ar atmosphere with a pressure of about 100 Pa to 10000 Pa, the temperature of the raw material 50 is set to about 2100 °C to 2400 °C, and the temperature of the seed crystal 40 is set to about 2000 °C to 2300 °C, which is lower than the temperature of the raw material 50.

The atmosphere in the chamber is obtained, for example, by introducing inert gas such as Ar gas through an air-supply pipe (not illustrated) while discharging air or the like through an exhaust pipe (not illustrated). Until the temperature of a growth surface (surface 40a) of the seed crystal 40 and the temperature of the raw material 50 are raised to target temperatures, the inside of the heating chamber is set, for example, to an atmosphere pressure close to the atmospheric pressure to suppress sublimation from the raw material 50, and when the target temperatures are reached, the inside of the heating chamber is set to the reduced pressure atmosphere described above.

As described above, by heating the raw material 50 under the reduced pressure atmosphere, the raw material 50 is sublimated, and a sublimation gas is generated from the raw material 50. This sublimation gas is supplied to the surface 40a of the seed crystal 40. As a result, the sublimation gas crystallizes on the surface 40a of the seed crystal 40, and the SiC single crystal 60 grows. In order to control the resistivity of the crystal, nitrogen gas is introduced and flowed in as needed.

In the crucible 1, the side surface 12 of the growth space 11 is covered with the cover member 30 made of a metal carbide having a melting point higher than the growth temperature of SiC. Further, a predetermined region of the side surface 12 from the height position 1A of the seed crystal 40 is covered with the cover member 30 so that the coverage ratio is in the range from 5% to 80%, and graphite is exposed in the remainder of the side surface 12. As a result, the graphite of the side surface 12 is not exposed in the vicinity of the seed crystal 40, and it is possible to suppress carbon derived from the graphite from being mixed into the SiC single crystal 60. In addition, since the graphite is exposed from the cover member 30 in a region of the side surface 12 far from the seed crystal 40, it is possible to suppress partial consumption of the graphite on the side surface 12 in the growth process of the SiC single crystal 60 while suppressing Si in the sublimation gas of the raw material 50 from becoming excessive.

According to the present embodiment, the SiC single crystal manufacturing apparatus and the SiC single crystal manufacturing method can suppress deterioration of crystal quality of the SiC single crystal 60 caused by incorporation of carbon derived from the graphite of the crucible 1 and local consumption of the crucible 1.

(1) When the coverage ratio of the side surface 12 by the cover member 30 is 5% or more and 80% or less, more preferably 10% or more and 60% or less, the carbon inclusion density in the SiC single crystal 60 becomes a predetermined value or less. Thus, it becomes possible to ensure favorable crystal quality. Here, for example, in a closed space of the crucible 1 closed by the lid 20 in a state before placing the raw material 50, a ratio of dimensions in the height direction of the raw material arrangement region and the remaining region (corresponding to the growth space 11) is defined as α : β (α and β are any positive numbers). In this case, the cover member 30 may be disposed so that the coverage ratio is 5% or more and 80% or less, more preferably 10% or more and 60% or less on the wall surface of a region up to a ratio of β/(α+β) downward from the end portion on the lid 20 side in the closed space described above.

(2) By growing the SiC single crystal 60 in a range covered with the cover member 30, incorporation of carbon derived from the exposed graphite of the side surface into the SiC single crystal 60 is suppressed, and it becomes possible to ensure favorable crystal quality. In other words, when a height from the surface 40a of the seed crystal 40 to the surface 60a of the SiC single crystal 60 along the normal direction to the surface 40a is referred to as a crystal height, the crystal height of the SiC single crystal 60 may be in the range of the region covered with the cover member 30.

(3) By forming the cover member 30 of the carbide of any one of tantalum, niobium, tungsten, and titanium, the melting point of the cover member 30 exceeds 2500 °C. As a result, at the growth temperature of the SiC single crystal 60, the cover member 30 can maintain a stable shape, and the growth process of the SiC single crystal 60 can be performed stably.

(4) By forming the cover member 30 of tantalum carbide and setting the C/Ta ratio in the range of 0.2 or more and 1 or less, the rate of change in dimension and weight before and after the carburization treatment to obtain the cover member 30 can be suppressed in a range from 1% to 10%. As a result, the cover member 30 can be maintained in a stable shape and dimensions in the SiC crystal growth process.

### Second Embodiment

A SiC single crystal manufacturing apparatus according to a second embodiment will be described with reference to the drawings.

The SiC single crystal manufacturing apparatus of the present embodiment differs from the first embodiment in that the crucible 1 further has a skirt portion 70 as illustrated in FIG. 3, for example. In the present embodiment, this difference will be mainly described.

In the crucible 1 of the present embodiment, for example, the lid 20 has a circular pillar-shaped protrusion 21, and the container body 10 has a skirt portion 70 surrounding the seed crystal 40 in the vicinity of the seed crystal 40. The seed crystal 40 is attached at a tip position of the protrusion 21. As illustrated in FIG. 3 and FIG. 4, for example, the skirt portion 70 has a truncated-cone shape having openings at upper and lower sides, and an inner peripheral surface 70a of the skirt portion 70 is covered with the cover member 30. Of the upper and lower openings of the skirt portion 70, the opening having a smaller diameter is disposed in the vicinity of the seed crystal 40. Hereinafter, for convenience of description, of the upper and lower openings of the skirt portion 70, the opening having a smaller diameter corresponding to an upper base surface of the truncated-cone shape may be referred to as a “small opening”, and the opening having a larger diameter corresponding to a lower base surface may be referred to as a “large opening”. The skirt portion 70 serves to expand the diameter of the grown crystal when growing the SiC single crystal 60 on the seed crystal 40, and may also be referred to as, for example, a growth guide. In the skirt portion 70, an inclination angle of the inner peripheral surface 70a, defined as an angle between an imaginary line along a central axis passing through the centers of the upper and lower openings and the inner peripheral surface 70a, is 45° or less, for example.

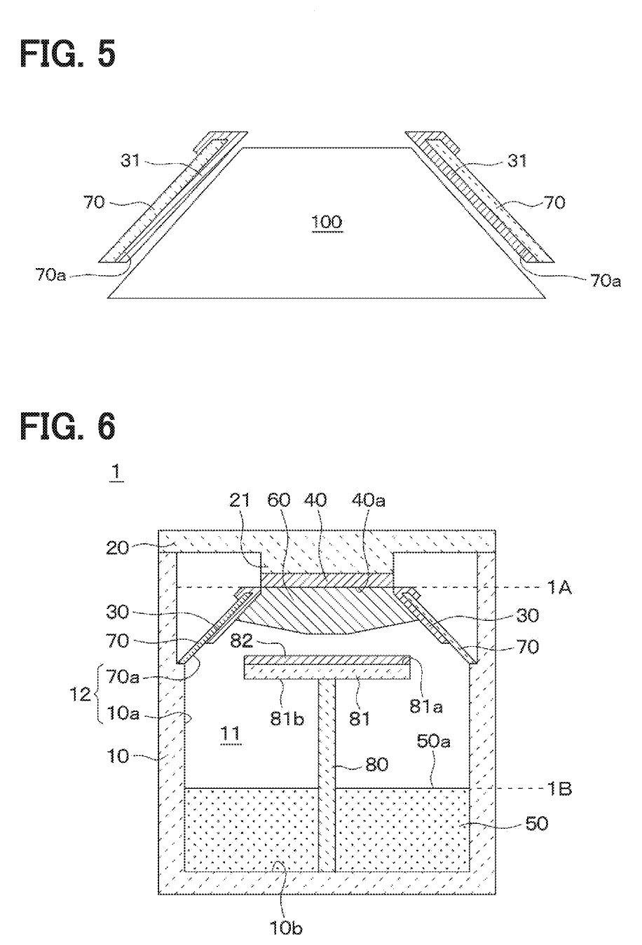

The skirt portion 70 is made of, for example, graphite, and the cover member 30 is fixed to the inner peripheral surface 70a. The cover member 30 attached to the skirt portion 70 is produced, for example, by the following process. For example, as illustrated in FIG. 5, a plate material 31 having a thickness of 0.1 mm to 3 mm made of a metal material, such as Ta, is prepared, and deep drawing is performed on the plate material 31 to shape the plate material 31 into a shape corresponding to the inner peripheral surface 70a of the skirt portion 70. Subsequently, for example, by bending a portion of the plate material 31 by seaming or crimping to secure it to the small opening of the skirt portion 70, the plate material 31 is in a state of covering the inner peripheral surface 70a of the skirt portion 70. Thereafter, a graphite member 100 having a shape along the inner peripheral surface 70a of the skirt portion 70 is prepared, and the plate material 31 attached to the skirt portion 70 is placed adjacent to the graphite member 100. Then, for example, the plate material 31 is subjected to a heat treatment at 1500 °C or higher and 2500 °C or lower in an argon atmosphere, so that the plate material 31 is carburized to become a metal carbide having a melting point higher than the growth temperature of SiC. Accordingly, the skirt portion 70 has a configuration in which a part or an entirety of the inner peripheral surface 70a and the vicinity of the small opening are covered with the cover member 30 made of the metal carbide.

In the present embodiment, the growth space 11 is surrounded by the inner wall surface 10a of the container body 10 and the inner peripheral surface 70a of the skirt portion 70. That is, in the present embodiment, the side surface 12 is composed of a region of the inner wall surface 10a of the container body 10 from the large opening of the skirt portion 70 to the surface 50a of the raw material 50, and the inner peripheral surface 70a of the skirt portion 70. The cover member 30 covers a predetermined region of the side surface 12 including the inner peripheral surface 70a from the height position 1A of the seed crystal 40 toward the height position 1B, so that the coverage ratio of the side surface 12 is 5% or more and 80% or less. The cover member 30 may be disposed to cover a part of the inner peripheral surface 70a, or may be disposed to cover the entire area of the inner peripheral surface 70a, or additionally a part of the inner wall surface 10a. The coverage range of the side surface 12 with the cover member 30 may be appropriately changed according to a desired crystal height of the SiC single crystal 60 to be obtained. Also in the present embodiment, the SiC single crystal 60 is obtained by growing in the range covered by the cover member 30, with the lower end of the cover member 30 of the side surface 12 as the upper limit of the crystal height.

According to the present embodiment, the apparatus and the method for manufacturing a SiC single crystal can achieve the same effects as those of the first embodiment. Further, since the crucible 1 has the truncated-cone-shaped skirt portion 70 and the small opening of the skirt portion 70 is disposed aligned with the height position 1A of the seed crystal 40, it is possible to grow the SiC single crystal 60 to have a diameter larger than that of the seed crystal 40. FIG. 3 illustrates an example in which the upper end position of the cover member 30 covering the skirt portion 70 coincides with the height position 1A of the surface 40a of the seed crystal 40. However, the present disclosure is not limited to this example, and these positions may substantially coincide. The phrase “substantially coincide” includes not only a case where the upper end position of the cover member 30 coincides with the height position 1A of the seed crystal 40, but also a case where the upper end position of the cover member 30 is above or below the height position 1A due to errors in dimensions of the skirt portion 70 or attachment to the container body 10, for example. In addition, the phrase “substantially coincide” also includes a case where the upper end position of the cover member 30 is intentionally disposed above or below the height position 1A within a range that does not hinder growth of the SiC single crystal 60 on the surface 40a of the seed crystal 40. For this reason, the skirt portion 70 may be disposed so that the upper end of the part covered with the cover member 30 coincides with the surface 40a of the seed crystal 40 in the height direction, may be disposed to have a gap with the surface 40a, or may be disposed to overlap with the seed crystal 40.

### Third Embodiment

A SiC single crystal manufacturing apparatus according to a third embodiment will be described with reference to the drawings.

The SiC single crystal manufacturing apparatus of the present embodiment differs from the first embodiment in that, as illustrated in FIG. 6, for example, the crucible 1 further has a pillar portion 80 extending from the bottom surface 10b of the container body 10 and a baffle plate 81, in addition to the skirt portion 70. Since the skirt portion 70 is the same as that in the second embodiment, the pillar portion 80 and the baffle plate 81 will be mainly described in the present embodiment.

The pillar portion 80 has, for example, a circular columnar or rod shape and extends from the center of the bottom surface 10b of the container body 10 toward the opening along the central axis of the crucible 1. The pillar portion 80 is made of, for example, a material having a melting point higher than that of the raw material 50, such as graphite, similarly to the container body 10.

The baffle plate 81 has, for example, a disk shape and is attached to a tip of the pillar portion 80. The baffle plate 81 is made of, for example, a material having a melting point higher than the growth temperature of SiC, such as graphite, similarly to the pillar portion 80. An upper surface 81a of the baffle plate 81 on a side opposite to a lower surface 81b is covered with a covering material 82. The pillar portion 80 is connected to the center of the lower surface 81b on the bottom surface 10b side of the baffle plate 81, and the baffle plate 81 serves to suppress contamination by foreign matter from the raw material 50 when the SiC single crystal 60 is grown to be long, that is, until the crystal height becomes large. Specifically, when the crystal height of the SiC single crystal 60 is large, that is, the SiC single crystal 60 is made long, the surface 60a of the SiC single crystal 60 approaches the surface 50a of the raw material 50. In such a case, there is a possibility that carbon inclusions from the raw material 50 may be mixed into the SiC single crystal 60. In the present embodiment, the baffle plate 81 is provided in the growth space 11 in order to block such foreign matter caused by the raw material 50 and to suppress mixing such foreign matter into the SiC single crystal 60.

The baffle plate 81 is disposed, for example, in the vicinity of the lower end of the cover member 30. For example, as illustrated in FIG. 6, when the cover member 30 covers only a part of the inner peripheral surface 70a of the skirt portion 70, the baffle plate 81 is disposed at a position closer to the seed crystal 40 than the large opening of the skirt portion 70. Note that the height position of the baffle plate 81 may be set independently of the coverage range with the cover member 30. Further, the covering material 82 may be formed to not only the upper surface 81a of the baffle plate 81, but also the entirety of the baffle plate 81.

The covering material 82 is made of, for example, the metal carbide having a melting point higher than the growth temperature of SiC, similarly to the cover member 30. The covering material 82 is made of, for example, a carbide of any one of tantalum, niobium, tungsten, and titanium. The covering material 82 is manufactured, for example, by a method similar to that for the cover member 30. The covering material 82 may be made of the same material as the cover member 30, or may be made of a material different from the cover member 30.

When the pillar portion 80 and the baffle plate 81 are made of graphite, whether or not the graphite portion other than the upper surface 81a among these members is covered with the covering material 82 is arbitrary, and is irrelevant to the coverage ratio of the side surface 12 by the cover member 30.

According to the present embodiment, the SiC single crystal manufacturing apparatus includes the crucible 1 that can achieve the same effects as those of the second embodiment. Further, since the SiC single crystal manufacturing apparatus further includes the baffle plate 81 whose upper surface 81a is covered with the covering material 82, it is possible to suppress foreign matter caused by the raw material 50 from being mixed into the SiC single crystal 60. In addition, the SiC single crystal manufacturing apparatus can manufacture a longer SiC single crystal 60.

Although the example in which the crucible 1 of the second embodiment has the pillar portion 80, the baffle plate 81, and the covering material 82 has been illustrated as the SiC single crystal manufacturing apparatus of the present embodiment, the present disclosure is not limited thereto. For example, as illustrated in FIG. 7, the SiC single crystal manufacturing apparatus of the present embodiment may have a configuration in which the crucible 1 of the first embodiment has the pillar portion 80, the baffle plate 81, and the covering material 82.

### Other Embodiments

The present disclosure has been described according to embodiments; however, it should be understood that the present disclosure is not limited to such embodiments or structures. The present disclosure encompasses various modifications and modifications within an equivalent range. In addition, various combinations and forms, and further, other combinations and forms including only one element thereof, more, or less, are also within the scope and concept of the present disclosure.

In each of the embodiments described above, it goes without saying that elements constituting the embodiment are not necessarily essential, except when explicitly stated as essential or when considered to be clearly essential in principle. In addition, in each of the above embodiments, when numerical values such as the number, numerical value, quantity, range, etc. of the components of the embodiment are mentioned, they are not limited to the specific number, except when explicitly stated as essential or when limited to a specific number clearly in principle. Furthermore, in each of the above embodiments, when referring to the shape, positional relationship, etc. of components, etc., they are not limited to the shape, positional relationship, etc., except when explicitly stated or when limited to a specific shape, positional relationship, etc. in principle.

What is claimed is:

1. A method for manufacturing a silicon carbide single crystal, the method comprising:
preparing a crucible having a hollow cylindrical shape, the crucible including a container body having a bottomed cylindrical shape, a lid closing an opening of the container body, and a cover member disposed inside the container body and made of a metal carbide having a melting point higher than a growth temperature of silicon carbide;
arranging a seed crystal composed of a silicon carbide substrate on the lid;
arranging a silicon carbide raw material in the container body; and
growing the silicon carbide single crystal on the seed crystal by supplying a sublimation gas of the silicon carbide raw material, wherein
a space in the crucible from a height position of a surface of the seed crystal to a height position of a surface of the silicon carbide raw material and that is filled with the sublimation gas is referred to as a growth space,
a wall surface of the growth space is referred to as a side surface, and
in the preparing of the crucible, the cover member has a tubular shape along the side surface and covers a predetermined region that is a part of the side surface from the height position of the surface of the seed crystal and corresponds to 5% or more and 80% or less of an area of the side surface.

2. The method according to claim 1, wherein
in the preparing of the crucible, the cover member covers 10% or more and 60% or less of the area of the side surface.

3. The method according to claim 1, wherein
in the growing of the silicon carbide single crystal, a height of the silicon carbide single crystal from the surface of the seed crystal to an outermost surface of the silicon carbide single crystal on a silicon carbide raw material side is referred to as a crystal height, and
the silicon carbide single crystal is grown so that the crystal height is in a range of the predetermined region of the side surface covered with the cover member.

4. The method according to claim 1, wherein
in the preparing of the crucible, the crucible includes a skirt portion attached to the container body,
the skirt portion has an opening surrounding the surface of the seed crystal and increases in diameter as a function of distance from the seed crystal, and
the cover member covers only a part of an inner peripheral surface of the skirt portion as the side surface.

5. The method according to claim 4, wherein
the opening of the skirt portion adjacent to the seed crystal is referred to as a small opening,
the skirt portion has a large opening having a larger diameter than the small opening on an opposite side to the small opening, and
the cover member covers only the part of the inner peripheral surface of the skirt portion that begins from an end at the small opening toward the large opening.

6. The method according to claim 1, wherein
the preparing of the crucible includes forming the cover member of a carbide of one selected from a group consisting of tantalum, niobium, tungsten, and titanium.

7. The method according to claim 6, wherein
the preparing of the crucible includes forming the cover member of tantalum carbide in which a C/Ta ratio, which is a ratio of carbon to tantalum, is in a range from 0.2 to 1.

8. The method according to claim 7, wherein
the preparing of the crucible includes carburizing a tantalum member to form the cover member of the tantalum carbide, so that a rate of change of each of weight and dimension of the tantalum member after carburization is 1% or more and 10% or less, relative to the weight and dimension before carburization.

9. The method according to claim 1, wherein
in the preparing of the crucible, the crucible includes a baffle plate disposed in the growth space, and
the baffle plate has an upper surface facing the seed crystal and being covered with a covering material made of a carbide having a melting point higher than that of the silicon carbide.

10. An apparatus for manufacturing a silicon carbide single crystal, the apparatus comprising:
a crucible that includes:
a container body having a bottomed cylindrical shape;
a lid closing an opening of the container body and having a surface to which a seed crystal composed of a silicon carbide substrate is to be attached; and
a cover member made of a metal carbide having a melting point higher than a growth temperature of silicon carbide, wherein
in the crucible, a direction from a bottom surface of the container body on which a silicon carbide raw material is disposed toward the lid is referred to as a height direction, a position corresponding to a surface of the silicon carbide raw material in the height direction is referred to as a raw material height position, a position corresponding to a surface of the seed crystal in the height direction is referred to as a seed crystal height position, a space from the raw material height position to the seed crystal height position and that is to be filled with a sublimation gas of the silicon carbide raw material is referred to as a growth space, and a wall surface of the crucible in the growth space is referred to as a side surface, and
the cover member has a tubular shape along the side surface and covers a predetermined region that is a part of the side surface from the seed crystal height position toward the raw material height position and corresponds to 5% or more and 80% or less of an area of the side surface.

11. The apparatus according to claim 10, wherein
the cover member is made of tantalum carbide in which a C/Ta ratio, which is a ratio of carbon to tantalum, is in a range from 0.2 to 1.
